(19) United States
(12) Patent Application Publication
(10) Pub. No.: US 2015/0237736 A1
(43) Pub. Date: Aug. 20, 2015

(54) METHOD OF PRODUCTION OF CIRCUIT BOARD

(71) Applicant: ZEON CORPORATION, Tokyo (JP)

(72) Inventor: Takashi Iga, Tokyo (JP)

(73) Assignee: ZEON CORPORATION, Tokyo (JP)

(21) Appl. No.: 14/424,854

(22) PCT Filed: Aug. 23, 2013
(86) PCT No.: PCT/JP2013/072510

§ 371 Date: Feb. 27, 2015

(30) Foreign Application Priority Data
Aug. 27, 2012 (JP) 2012-186412

(51) Int. Cl. H05K 3/00; H05K 3/18; H05K 1/03; H05K 3/10

(52) U.S. Cl. CPC H05K 3/0014; H05K 3/0044; H05K 3/107; H05K 3/182; H05K 1/032; H05K 2201/0166; H05K 2201/09036

(57) ABSTRACT

A method of production of a circuit board comprising a step of forming resist patterns 20 on a support 10 by a photoresist to obtain a support with resist patterns, a step of forming a curable resin composition layer 30 which is comprised of a curable resin composition on the resist patterns 20 of the support with resist patterns, a step of laying a substrate 40 on the curable resin composition layer 30, a step of making the curable resin composition which forms the curable resin composition layer 30 cure to make the curable resin composition layer 30 a cured resin layer 30a, a step of peeling off the support 10 from the curable resin composition layer 30 or the cured resin layer 30a and the resist patterns 20 before or after making the curable resin composition cure, a step of peeling off or dissolving the resist patterns 20 to remove the resist patterns 20 from the cured resin layer 30a so as to form a cured resin layer which has relief structures, and a step of forming fine wirings 50 by plating recesses of the relief structures which are formed at the cured resin layer 30a.

### TECHNICAL FIELD

The present invention relates to a method of production of a circuit board.

### BACKGROUND ART

Along with the increasingly smaller size and increasing thinness of electronic components, electronic devices, etc. in recent years, increasingly smaller size and increasing thinness have been sought from the circuit boards which are used for these as well. For this reason, along with this, in the circuit boards, it is required to be excellent electrical characteristics and also form the higher density circuit wiring patterns.

To form such higher density circuit wiring patterns, micronization of circuit wiring patterns has been studied. For example Patent Document 1 discloses a method of forming trenches in a substrate by laser ablation or imprint, treating this by a chemical or plasma to remove the residual substrate resulting from the formation of the trenches, then forming an electroless plating layer on the surface of the substrate and the inside surface of the trenches so as to produce a circuit board which is provided with predetermined wiring patterns.

### PRIOR ART DOCUMENTS

### Patent Documents

Patent Document 1: Japanese Patent Publication No. 2005-49364A

### SUMMARY OF THE INVENTION

### Problem to be Solved by the Invention

However, in the method of forming trenches by an excimer laser or other laser described in the art of Patent Document 1, the sizes of the trenches which are formed depend on the characteristics of the laser, so with the method of forming trenches by a laser, there were limits to micronization of wirings. Further, when using the method of forming trenches by a laser, there was also the problem of a higher cost of production.

Furthermore, in the method of forming trenches by imprint, when peeling off the mold for forming the fine wiring patterns from the substrate, it is extremely difficult to peel it off while maintaining well the fine wiring patterns formed by the mold. Therefore, even with the method of forming trenches by imprint, there were limits to micronization of wirings. Further, when using the method of forming trenches by imprint, it was necessary to treat the mold for forming the fine wiring patterns to enable release. There was the problem that the production steps became complicated.

An object of the present invention is to provide a method for producing a circuit board which can be made lower in height and can be micronized in wirings and which has excellent electrical characteristics (in particular, electrical insulating property).

### Means for Solving the Problems

The present inventors etc. discovered that the above object can be achieved by using, as the mold for forming the relief patterns when forming a cured resin layer which is provided with relief patterns for forming fine wirings, a mold comprised of a photoresist corresponding to the relief patterns and thereby completed the present invention. In particular, the present inventors etc. discovered that, by using the mold comprised of the photoresist, when removing the mold comprised of the photoresist after forming fine wiring patterns, it is possible to remove the mold comprised of the photoresist by treating the photoresist by a solution able to peel off it or dissolve it and thereby micronize the wirings and thus completed the present invention.

That is, according to the present invention, there are provided
[1] a method of production of a circuit board comprising:

a step of forming resist patterns on a support by a photoresist to obtain a support with resist patterns; a step of forming a curable resin composition layer which is comprised of a curable resin composition on the resist patterns of the support with resist patterns; a step of laminating a substrate on the curable resin composition layer; a step of making the curable resin composition which forms the curable resin composition layer cure to make the curable resin composition layer a cured resin layer; a step of peeling off the support from the curable resin composition layer or the cured resin layer and the resist patterns before or after making the curable resin composition cure; a step of peeling off or dissolving the resist patterns so as to remove the resist patterns from the cured resin layer to form a cured resin layer which has relief structures; and a step of forming fine wirings by plating recesses of the relief structures which are formed at the cured resin layer,
[2] a method of production of a circuit board comprising:

a step of forming resist patterns on a support by a photoresist to obtain a support with resist patterns; a step of forming a curable resin composition layer which is comprised of a curable resin composition on a substrate to obtain a curable resin composition substrate; a step of making the resist patterns of the support with resist patterns and the curable resin composition layer of the curable resin composition substrate into contact to laminate them so as to embed the resist patterns in the curable resin composition layer; a step of making the curable resin composition which forms the curable resin composition layer care to make the curable resin composition layer a cured resin layer; a step of peeling off the support from the curable resin composition layer or the cured resin layer and the resist patterns before or after making the curable resin composition cure; a step of peeling off or dissolving the resist patterns so as to remove the resist patterns from the cured resin layer to form a cured resin layer which has relief structures; and a step of forming fine wirings by plating recesses of the relief structures which are formed at the cured resin layer,
[3] the method of production of a circuit board according to [1] or [2] wherein the curable resin composition includes a curable resin constituted by an alicyclic olefin polymer,
[4] the method of production of a circuit board according to any one of [1] to [3] wherein the substrate has an electrical insulating layer, and a conductor circuit layer which is formed on one or both surfaces of the electrical insulating layer,
[5] the method of production of a circuit board according to any one of [1] to [4] further comprising a step of roughening the surface of the cured resin layer simultaneously with peeling off or dissolving the resist patterns, or after peeling off or dissolving the resist patterns,
[6] the method of production of a circuit board according to any one of [1] to [5] wherein the steps are performed on both surfaces of the substrate so as to form fine wirings in recesses of the cured resin layers which have relief structures at both surfaces of the substrate, and
[7] a circuit board which is obtained by a method of production of any of [1] to [6].

### Effects of the Invention

According to the present invention, there can be provided a circuit board which can be made lower in height and can be micronized in wirings and which has excellent electrical characteristics (in particular, electrical insulating property).

### BRIEF DESCRIPTION OF DRAWINGS

FIG. 1 is a view which shows a method of production of a circuit board according to an embodiment of the present invention.

FIG. 2 is a view which shows a method of production of a circuit board according to an embodiment of the present invention.

FIG. 3 is a view which shows a method of production of a circuit board according to another embodiment of the present invention.

FIG. 4 is a view which shows a method of production of a circuit board according to an example of the present invention.

### DESCRIPTION OF EMBODIMENTS

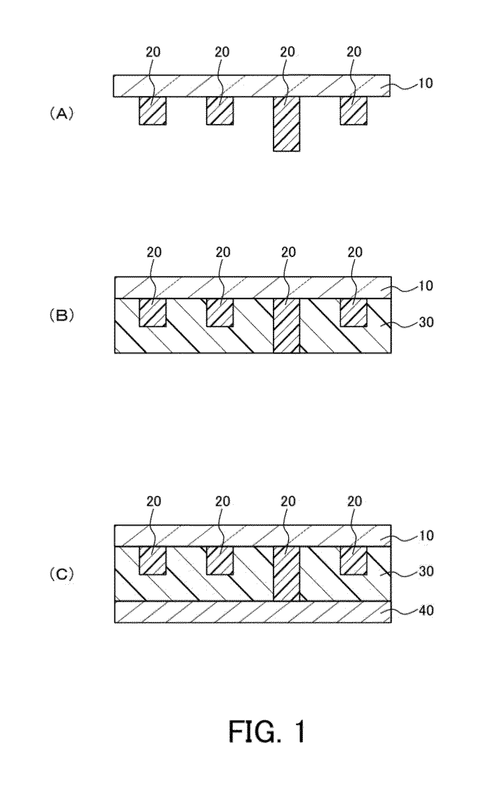

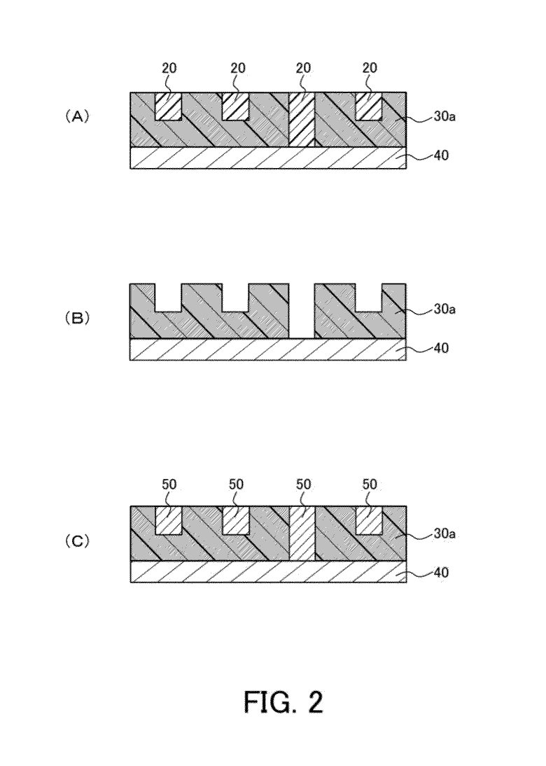

Below, a method of production of a circuit board of the present invention will be explained while referring to FIG. 1 and FIG. 2.

The method of production of a circuit board of the present invention is a method for production of a circuit board which is comprised of a substrate 40 on which fine wirings 50 are formed by predetermined patterns (see FIG. 2(C)).

The method of production of a circuit board of the present invention has the following steps:

(Step A) Step of forming resist patterns 20 on a support 10 by a photoresist to obtain a support with resist patterns (see FIG. 1(A)).

(Step B) Step of forming a curable resin composition layer 30 comprised of a curable resin composition on the resist patterns 20 of the support with resist patterns (see FIG. 1(B)).

(Step C) Step of laminating a substrate 40 on the curable resin composition layer 30 (see FIG. 1(C)).

(Step D) Step of making the curable resin composition which forms the curable resin composition layer 30 cure so as to make the curable resin composition layer 30 a cured resin layer 30a (see FIG. 2(A)).

(Step E) Step of peeling off the support 10 from the curable resin composition layer 30 or the cured resin layer 30a and the resist patterns 20 before or after making the curable resin composition cure (see FIG. 2(A)).

(Step F) Step of peeling off or dissolving the resist patterns 20 so as to remove the resist patterns 20 from the cured resin layer 30a thereby to form a cured resin layer 30a which has relief structures (see FIG. 2(B)).

(Step G) Step of forming fine wirings 30 by plating recesses of the relief structures which are formed at the cured resin layer 30a (see FIG. 2(C)).

Below, the steps will be explained in detail.

(Step A)

Step A is a step of forming resist patterns 20 on a support 10 by a photoresist to obtain, as shown in FIG. 1(A), a support 10 which has resist patterns 20, that is, a support with resist patterns.

The support 10 which is used in Step A is not particularly limited, but a film-shaped, sheet-shaped, or other member can be used. For example, a polyethylene terephthalate film, polypropylene film, polyethylene film, polycarbonate film, polyethylene naphthalate film, polyarylate film, nylon film, polytetrafluoroethylene film, or other polymer film or a sheet-shaped or film-shaped glass base material etc. may be mentioned. Note that, the support 10 may also be treated by release treatment on the surface for forming the resist patterns 20 so as to facilitate peeling at a later step.

Further, the method of forming the resist patterns 20 on the support 10 is not particularly limited, but, for example, the following method may be mentioned. That is, the support 10 is coated with a photoresist composition or a dry film comprised of a photoresist composition is laminated on it to form a photoresist film on the support 10. Next, the photoresist film is irradiated with activating light through mask patterns to form latent patterns in the photoresist film and the film is brought into contact with an alkali developer so as to develop the patterns and thereby form the resist patterns 20. Note that, the photoresist composition which is used in this case may be either a positive type composition or a negative type composition.

As the photoresist composition which is used in the present invention, one which contains an alkali-soluble resin and photosensitizing agent may be mentioned. The alkali-soluble resin is not particularly limited so long as a resin which is soluble in a developer which is comprised of an alkali aqueous solution etc.

The alkali-soluble resin is not particularly limited so long as a resin which is soluble in a developer which is comprised of an alkali aqueous solution etc. A resin which is used for a known photoresist composition, for example, a novolac resin, resole resin, acrylic resin, polyvinyl alcohol, styrene-acrylic acid copolymer, hydroxystyrene polymer, polyvinyl hydroxybenzoate, etc. may be mentioned.

Further, when a positive type composition, as the photosensitizing agent, a quinone diazide-group containing compound may be mentioned as a typical example. Alternatively, when a negative type composition, as the photosensitizing agent, a compound which generates an acid (acid generator) or a compound which generates radicals (radical generator) may be used. As the acid generator, for example, an onium salt, halogen-containing compound, diazoketone compound, sulfone compound, sulfonic acid compound, etc. may be mentioned. As the radical generator, for example, an alkylphenone-based photopolymerization initiator, acylphosphine oxide-based photopolymerization initiator, or other known compound may be used.

When forming the photoresist film on the support 10, when forming it by coating a photoresist composition, it is possible to coat a photoresist composition comprised of an alkali-soluble resin, photosensitizing agent and a solvent on the support 10, then dry off the solvent so as to form the photoresist film on the support 10. Alternatively, when laminating a dry film comprised of a photoresist composition to form the photoresist film, it is possible to hot press bond a commercially available dry film on the support 10 at preferably 80 to 120° C., more preferably 90 to 110° C., so as to form the photoresist on the support 10. Note that, as commercially available dry film, for example, as the positive type of dry film, “SRF SS7200” (made by Toagosei) etc. may be used. Further, as the negative type of dry film, “SUNFORT UFG” (made by Asahi Kasel E-materials), “NIT3025” (made by Nichigo-Morton), “SU-8 3000” (made by Nippon Kayaku), etc. may be used.

Next, the photoresist film which is formed on the support 10 is irradiated by activating light through the mask patterns so as to form latent patterns corresponding to the desired fine wiring patterns. The amount of exposure by the activating light is not particularly limited and may be suitably selected in accordance with the type of the photoresist composition. Note that, in the method of production of the present invention, when using a negative type composition as the photoresist composition, irradiating activating light from the support 10 side is preferable.

Here, if using a mask which is given semi-transparent parts as mask patterns, the amount of exposure can be controlled in accordance with the rate of light transmission of the mask patterns, so it is possible to form latent patterns corresponding to the desired fine wiring patterns with different resist film thicknesses after irradiating activating light. That is, it is possible to form latent patterns, for example, which have a part in which photoresist film thicknesses is close to initial thicknesses, a part in which photoresist film thicknesses is thinner due to irradiating, and a part in which photoresist is completely removed. Due to this, it is possible to form through holes, non-through holes, etc. in the cured resin layer at one time.

As the method of forming semi-transparent parts: on the photomask, the method of blurring the micropatterns to form semi-transparent parts, the method of laminating a film which has any transmission rate and thereby making patterns to form semi-transparent parts, etc. can be used.

Next, the photoresist film which is formed with the latent patterns is brought into contact with the alkali developer to develop the patterns and thereby form resist patterns 20 to obtain the support with resist patterns (support 10 which has resist patterns 20) as shown in FIG. 1(A). As the alkali developer which is used for development, for example, an alkali metal salt, amine, or ammonium salt can be used. Specifically, sodium hydroxide, potassium hydroxide, sodium carbonate, sodium silicate, metasodium silicate, or other alkali metal salts; ammonia water; ethylamine, n-propylamine, or other primary amines; diethylamine, di-n-propylamine, or other secondary amines; triethylamine, methyldiethylamine, or other tertiary amines; tetramethylammonium hydroxide, tetraethylanmonim hydroxide, tetrabutylammonium hydroxide, choline, or other quaternary ammonium salts; dimethylethanol amine, triethanol amine, or other alcohol amines; pyrrole, piperidine, 1,8-diazabicyclo[5.4.0]undeca-7-ene, 1,5-diazabicyclo[4.3.0]nona-5-ene, N-methylpyrrolidone, or other cyclic amines; etc. may be mentioned.

Further, as the method of bringing the photoresist film formed with the latent patterns into contact with the alkali developer, for example, the puddle method, spray method, dipping method, etc. may be used. The conditions when performing the development are suitably set to usually 0 to 100° C., preferably 5 to 55° C., more preferably 10 to 30° C. in range, usually for 30 to 180 seconds in range.

Further, the thus obtained support with resist patterns may be rinsed by a rinse solution in accordance with need so as to remove the development residue. In this case, after the rinse treatment, it is desirable to remove the remaining rinse solution by compressed air or compressed nitrogen.

(Step B)

Step B is a step of forming on the resist patterns 20 of the support with resist patterns obtained at Step A (see. FIG. 1(A)) a curable resin composition layer 30 comprised of a curable resin composition containing a curable resin and curing agent so as to obtain, as shown in FIG. 1(B), a support 10 which has resist patterns 20 and a curable resin composition layer 30. The curable resin composition layer 30, as explained later, is a layer which is to form the cured resin layer 30a (see FIG. 2(C)) by curing and form an electrical insulating layer in the circuit board.

In the method of production of the present invention, the curable resin composition layer 30 is preferably formed as an uncured or semicured resin layer. An “uncured resin layer” is a layer in the state where substantially all of the resin layer can be dissolved in a solvent in which the thermosetting resin which forms the resin layer can be dissolved. A “semicured resin layer” is a layer in the state cured to an extent where further curing is possible by heating and a state where a part can be dissolved in a solvent in which the thermosetting resin which forms the resin layer can be dissolved.

The method of forming the curable resin composition layer 30 is not particularly limited, but the method of coating the surface of the support with resist patterns on which the resist patterns 20 are formed with a curable resin composition and making it dry so as to form the curable resin composition layer 30 etc. may be mentioned.

The curable resin composition for forming the curable resin composition layer 30 usually contains a curable resin and curing agent. The curable resin is not particularly limited so long as exhibiting thermosetting property by combination with a curing agent and having an electrical insulating property, but, for example, an epoxy resin, maleimide resin, (meth)acrylic resin, diallyl phthalate resin, triazine resin, alicyclic olefin polymer, aromatic polyether polymer, benzocyclobutene polymer, cyanate ester polymer, polyimide, etc. may be mentioned. These resins are used respectively alone or as two types or more combined. Among these as well, an alicyclic olefin polymer, aromatic polyether polymer, benzocyclobutene polymer, cyanate ester polymer, and polyimide are preferable, an alicyclic olefin polymer and aromatic polyether polymer are more preferable, and an alicyclic olefin polymer is particularly preferable. In addition to these polymers, a liquid crystal polymer can also be used as a preferable thermosetting resin. As the liquid crystal polymer, a polymer of an aromatic or aliphatic dihydroxy compound, a polymer of an aromatic or aliphatic dicarboxylic acid, a polymer of an aromatic hydroxycarboxylic acid, a polymer of an aromatic diamine, aromatic hydroxyamine, or aromatic aminocarboxylic acid, etc. may be illustrated. Note that, in this Description, “(meth)acrylic” means methacrylic or acrylic.

The weight average molecular weight (Mw) of the curable resin is not particularly limited, but is usually 3,000 to 1,000,000, preferably 4,000 to 500,000. In this Description, the weight average molecular weight (Mw) is the weight average molecular weight converted to polystyrene measured by gel permeation chromatography (GPC) using tetrahydrofuran as an eluent.

The alicyclic olefin polymer is a polymer of an unsaturated hydrocarbon which has en alicyclic structure. As the alicyclic structure, a cycloalkane structure, cycloalkene structure, etc. may be mentioned, but from the viewpoint of raising the obtained cured resin layer 30a in mechanical strength, heat resistance, etc., a cycloalkane structure is preferable. Further, the alicyclic structure may be any of a monocyclic structure and polycyclic structure (condensed polycyclic structure, bridged cyclic structure, combined polycyclic structure of the same, etc.). The number of carbon atoms which form the alicyclic structure is not particularly limited, but is usually 4 to 30, preferably 5 to 20, more preferably 5 to 15 in range. At this time, the various properties such as the moldability of the curable composition and the mechanical strength and heat resistance of the obtained cured resin layer 30a are balanced to a high degree, so this is preferable.

Further, as the alicyclic olefin polymer, one which has polar groups is preferable. As the polar group, a hydroxyl group, carboxyl group, alkoxyl group, epoxy group, glycidyl group, oxycarbonyl group, carbonyl group, amino group, ester group, carboxylic anhydride group, etc. may be mentioned. In particular, a carboxyl group and carboxylic anhydride group are preferable. In 100 mol % of the total repeating units which form the alicyclic olefin polymer, the content of the repeating units which have the polar groups is not particularly limited, but is usually 5 to 60 mol %, preferably 10 to 50 mol %. Note that, the number of the polar groups present in the repeating units is not particularly limited, but is usually 1 to 2.

The alicyclic olefin polymer is usually obtained by addition polymerization or ring-opening polymerization of an alicyclic olefin monomer and, if desired, hydrogenation of unsaturated bond parts or by addition polymerization of an aromatic olefin monomer and hydrogenation of the aromatic ring part of the obtained polymer. Further, the alicyclic olefin polymer having polar groups, for example, is obtained by (1) introducing polar groups into the alicyclic olefin polymer by a modification reaction, (2) copolymerizing monomers which contain polar groups as copolymerizing components, or (3) copolymerizing monomers containing ester groups or other polar groups as copolymerizing components, then hydrolyzing the ester groups etc. In the case of the above (1), it is possible to adjust the amount of introduction of polar groups, while in the case of the above (2) and (3), it is possible to suitably use monomers not having the specific polar groups at the time of polymerization so as to adjust the content of repeating units having polar groups in the alicyclic olefin polymer. Note that, in this Description, “alicyclic olefin monomer” means a monomer which has carbon-carbon double bonds in an alicyclic structure, while an “aromatic olefin monomer ” means a monomer which is comprised of chain hydrocarbons which have aromatic groups and carbon-carbon double bonds.

As the alicyclic olefin monomer for forming the alicyclic olefin polymer, bicyclo[2.2.1]-hept-2-ene (commonly used name: norbornene), 5-methyl-bicyclo[2.2.1]-hept-2-ene, 5,5-dimethyl-bicyclo[2.2.1]-hept-2-ene, 5-ethyl-bicyclo[2.2.1]-hept-2-ene, 5-butyl-bicyclo[2.2.1]-hept-2-ene,5-hexyl-bicyclo[2.2.1]-hept-2-ene, 5-octyl-bicyclo[2.2.1]-hept-2-ene, 5-octadecyl-bicyclo[2.2.1]-hept-2-ene, 5-ethylidene-bicyclo[2.2.1]-hept-2-ene, 5-methylidene-bicyclo[2.2.1]-hept-2-ene, 5-vinyl-bicyclo[2.2.1]-hept-2-ene,

5-propenyl-bicyclo[2.2.1]-hept-2-ene, 5-methoxy-carbonyl-bicyclo[2.2.1]-hept-2-ene, 5-cyano-bicyclo[2.2.1]-hept-2-ene, 5-methyl-5-methoxy carbonyl-bicyclo[2.2.1]-hept-2-ene, 5-ethoxycarbonyl-bicyclo[2.2.1]-hept-2-ene, bicyclo[2.21]-hept-5-enyl-2-methylpropionate, bicyclo[2.2.1]-hept-5-enyl-2-methyloctanate,

bicyclo[2.2.1]-hept-2-ene-5,6-dicarboxylic anhydride, 5-hydroxymethylbicyclo[2.2.1]-hept-2-ene, 5,6-di(hydroxymethyl)-bicyclo[2.2.1]-hept-2-ene, 5-hydroxy-i-propylbicyclo[2.2.1]-hept-2-ene, 56-dicarboxy-bicyclo[2.2.1]-hept-2-ene, bicyclo[2.2.1]-hept-2-ene-5 6-dicarboxylic acid imide, 5-cyclopentyl-bicyclo[2.2.1]-hept-2-ene, 5-cyclohexyl-bicyclo[2.2.1]-hept-2-ene, 5-cyclobezenyl-bicyclo[2.2.1]-hept-2-ene, 5-phenyl-bicyclo[2.2.1]-hept-2-ene,

tricyclo[4.3.1^{2,5}]deca-3,7-diene (commonly used name: dicyclopentadiene), tricyclo[4.3.0.1^{2,5}]dec-3-ene, tricycle [4.4.0.1^{2,5}]undeca-3,7-diene, tricyclo[4.4.0.1^{2,5}]undeca-3,8-diene, tricyclo[4.4.0.1^{2,5}]undec-3-ene, tetracyclo[7.4.0.1^{19,1}.3.0^{2,7}]-trideca-2,4,6-11-tetraene (other name: 1,4-methano-1,4,4a, 9a-tetrahydrofluorene, tetracyclo[8.4.0.1^{11,1}4.0^{3,8}]-tetradeca-3, 5, 7, 12,11-tetraene (other name: 1,4-methano-1, 4, 4a, 5, 10, 10a-hexahydroanthracene),

tetracyclo[4.4.0.1^{2,5}.1^{7,10}]-dodec-3-ene (commonly used name: tetracyclododecene), 8-methyl-tetracyclo[4.4.0.1^{2,5}.1^{7,10}]-dodec-3-ene, 8-ethyl-tetracyclo[4.4.0.1^{2,5}.1^{7,10}]-dodec-3-ene, 8methylidene-tetracyclo[4.4.0.1^{2,5}.1^{7,10}]-dodec-3-ene, 8-ethylidene-tetracyclo[4.4.0.1^{2,5}.1^{7,10}]-dodec-3-ene, 8-vinyl-tetracyclo[4.4.0.1^{2,5}.1^{7,10}]-dodec-3-ene, 8-propenyl-tetracyclo[4.4.0.1^{2,5}.1^{7,10}]-dodec-3-ene, 8-methoxycarbonyl-tetracyclo[4.4.0.1^{2,5}.1^{7,10}]-dodec-3-ene, 8-methyl-8-methoxy carbonyl-tetracyclo[4.4.0.1^{2,5}.1^{7,10}]-dodec-3-ene, 8-hydroxymethyl-tetracyclo[4.4.0.1^{2,5}.1^{7,10}]-dodec-3-ene, 8-carboxy-tetracyclo[4.4.0.1^{2,5}.1^{7,10}]-dodec-3-ene,

8-cyclopentyl-tetracyclo[4.4.0.1^{2,5}.1^{7,10}]-dodec-3-ene, 8-cyclohexyl-tetracyclo[4.4.0.1^{2,5}.1^{7,10}]-dodec-3-ene, 8-cyclohexenyl-tetracyclo[4.4.0.1^{2,5}.1^{7,10}]-dodec-3-ene, 8-phenyl-tetracyclo[4.4.0.1^{2,5}.1^{7,10}]-dodec-3-ene, pentacyclo[6.5.1.1^{3,6}.0^{2,7}.0^{9,13}]pentadeca-3,10-diene, and pentacyclo[7.4.0.1^{3,6}.1^{3.6}.1^{10,13}.0^{2,7}]-pentadeca-4,11-diene, or other norbornene-based monomer;

cyclobutene, cyclopentene, cyclohexene, 3, 4-dimethylcyclopentene, 3-methylcyclohexene, 2-(2-methylbutyl)-1-cyclohexene, cyclooctene, 3a,5,6,7a-tetrahydro-4,7-methano-1H-indene, cycloheptene, or other monocyclic cycloalkene-based monomers; vinyl cyclohexene, vinyl cyclohexane, or other vinyl-based alicyclic hydrocarbon-based monomers; cyclopentadiene, cyclohexadiene, or other alicyclic conjugated diene-based monomers; etc. may be mentioned.

As the aromatic olefin monomer, styrene, α-methylstyrene, divinylbenzene, etc. may be mntioned.

The alicyclic olefin monomer and/or aromatic olefin monomer respectively may be used alone or as two types or more combined.

Further, the alicyclic olefin polymer may also be one obtained by copolymerizing the above-mentioned alicyclic olefin monomer and/or aromatic olefin monomer and other monomers copolymerizable with the same.

As the copolymerizable other monomers, ethylene; propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4, 4-methyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, 1-eicosene, or other α-olefin having three to twenty carbon atoms; 1,4-hexadiene, 4-methyl-1,4-hexadiene, 5-methyl-1,4-hexadiene, 1,7-octadiene, or other nonconjugated dienes; etc. may be mentioned. These monomers can be respectively used alone or as two types or more combined.

The polymerization of the alicyclic olefin monomer or aromatic olefin monomer and the hydrogenation performed as desired are not particularly limited. They can be performed by known methods.

As specific examples of the alicyclic olefin polymer, a ring-opening polymer of a norbornene-based monomer and its hydrogenate, an addition polymer of a norbornene-based monomer, an addition polymer of a norbornene-based monomer and a vinyl compound, a monocyclic cycloalkene polymer, an alicyclic conjugated diene polymer, a vinyl-based alicyclic hydrocarbon polymer and its hydrogenate, an aromatic cyclic hydrogenate of an aromatic olefin polymer, etc. may be mentioned. Among these as well, a ring-opening polymer of a norbornene-based monomer and its hydrogenate, an addition polymer of a norbornene-based monomer, an addition polymer of a norbornene-based monomer and a vinyl compound, and an aromatic cyclic hydrogenate of an aromatic olefin polymer are preferable, particularly a hydrogenate of a ring-opening polymer of a norbornene-based monomer is preferable. These alicyclic olefin polymers respectively may be used alone or as two types or more combined.

The curing agent which is contained in the curable resin composition is not particularly limited, but for example an ionic curing agent, radical curing agent, combined ionic and radical caring agent, etc. may be used. As specific examples of the curing agent, 1-allyl-3,5-diglycidyl isocyanulate, 1,3-diallyl-5-glycidyl isocyanulate, or other allyl group- and epoxy-group-containing non-halogen-containing isocyanulate-based curing agent or other nitrogen-based caring agent; bisphenol A bis(ethyleneglycol glycidylether)ether, bisphenol A bis(diethyleneglycol glycidylether)ether, bisphenol A bis(triethyleneglycol glycidylether) ether, bisphenol A bis(propyleneglycol glycidylether)ether, or other bisphenol A-based glycidylether type epoxy compound or other glycidylether type epoxy compound, fluorene-based epoxy compound or other alicyclic epoxy compound, glycidyl ester type epoxy compound or other polyvalent epoxy compound; acid anhydride or dicarboxylic acid compound or other dicarboxylic acid derivative; diol compound, triol compound, and polyvalent phenol compound or other polyol compound; or other curing agents may be mentioned. These curing agents may be used independently or as two types of more combined. Among these as well, from the viewpoint of enabling the obtained cured resin layer 30a to be raised in mechanical strength, use of at least one type of compound which is selected from the group comprised of a polyvalent epoxy compound, dicarboxylic acid derivative, and polyol compound is preferable, while use of a polyvalent epoxy compound is more preferable.

Note that, the curable resin composition which is used in the present invention may further include, in addition to the above-mentioned curable resin and curing agent, a curing accelerator, filler, flame retardant, flame retardant aid, heat resistance stabilizer, weather resistance stabilizer, antiaging agent, leveling agent, antistatic agent, slip agent, antiblocking agent, anticlouding agent, lubricant, dye, natural oil, synthetic oil, wax, emulsion, magnetic substance, dielectric characteristic adjuster, toughness agent, etc.

In the present invention, the method of coating the surface of the support with resist patterns on which the resist patterns 20 are formed with the curable resin composition is not particularly limited, but the method of forming the curable resin composition by the solution casting method, melt casting method, etc. may be mentioned, but production by the solution casting method is preferable. When forming it by the solution casting method, a varnish of the curable resin composition is prepared, this is coated on the surface of the support with resist patterns on which the resist patterns 20 are formed, then the organic solvent is dried off.

The method of preparing the varnish of the curable resin composition is not particularly limited, but it is possible to prepare it by mixing the ingredients forming the curable resin composition and an organic solvent. As the organic solvent, for example, toluene, xylene, ethylbenzene, trimethylbenzene, anisole, or other aromatic hydrocarbon-based organic. solvent; h-pentane, n-hexane, n-heptane, or other aliphatic hydrocarbon-based organic solvent; cyclopentane, cyclohexane, or other alicyclic hydrocarbon-based organic solvent; chlorobenzene, dichlorobenzene, trichlorobenzene, or other halogenated hydrocarbon-based organic solvent; methylethylketone, methylisobutylketone, cyclopentanone, cyclohexanone, or of ketone-based organic solvent, etc. may be mentioned. These organic solvents respectively may be used alone or as two types or more combined.

The amount of use of the organic solvent is suitably selected in accordance with the control of the thickness of the curable resin composition layer 30 or improvement of flatness or other objectives, but the solid content concentration of the varnish is usually 5 to 70 wt %, preferably 10 to 65 wt %, more preferably 20 to 60 wt % in range.

As the coating method, a dip coat, roll coat, curtain coat, die coat, slit coat, or other method may be mentioned. Further, the conditions for drying to remove the organic solvent are preferably a temperature of an extent where the curable resin composition layer 30 does not cure so that the curable resin composition layer 30 becomes an uncured or semicured state. The drying temperature is usually 20 to 200° C., preferably 30 to 150° C., while the drying time is usually 30 seconds: to 1 hour, preferably 1 minute to 30 minutes.

The thickness of the curable resin composition layer 30 is usually 0.1 to 150 μm, preferably 0.5 to 100 μm, more preferably 1to 80 μm.

(Step C)

Step C is a step of laminating a substrate 40 on the surface of the support 10 having the resist patterns 20 and curable resin composition layer 30 obtained by Step B at the curable resin composition layer 30 side to obtain, as shown in FIG. 1(C), a precured laminate comprised of a support 10, resist patterns 20, curable resin composition layer 30, and substrate 40.

The substrate 40 is not particularly limited, but, for example, one which has an electrical insulating layer and which is formed with a conductor circuit layer on one surface or both surfaces of the electrical insulating layer may be mentioned. As a specific example of such a substrate 40, a printed circuit board or silicon wafer substrate etc. may be mentioned. The thickness of the substrate 40 is usually 10 μm to 2 mm, preferably 30 μm to 1.6 mm, more preferably 50 μm to 1 mm.

As the substrate 40, one where the electrical insulating layer which forms the substrate 40 is mainly comprised of a thermosetting resin which has an electrical insulating property is preferable. As such a thermosetting resin, for example, an alicyclic olefin polymer, epoxy resin, maleimide resin, (meth)acrylic resin, diallyl phthalate resin, triazine resin, aromatic polyether polymer, cyanate ester polymer, polyimide, etc. may be mentioned. Usually, it is possible to cure the curable composition containing these thermosetting resins and a curing agent to obtain an electrical insulating layer. Further, from the viewpoint of improvement of the strength, the substrate may be a electrical insulating layer which contains glass fiber, or resin fiber, etc. As the material for the conductor circuit layer forming the substrate 40, usually a conductive metal may be used.

In the method of production of the present invention, the method of laminating a substrate 40 on the curable resin composition layer 30 side of the surface of the support 10 which has the resist patterns 20 and curable resin composition layer 30 is not particularly limited, but the method of hot press bonding the substrate 40 on the curable resin composition layer 30 may be mentioned. The temperature at the time of hot press bonding is usually 30 to 250° C., preferably 70 to 200° C., the press bonding force is usually 10 to 20 MPa, preferably 100 kPa to 10 MPa, and the press bonding time is usually 30 seconds to 5 hours, preferably 1 minute to 3 hours. Further, to suppress the formation of bubbles etc., the hot press bonding may be performed under a reduced pressure atmosphere (preferably 100 kPa to 1 Pa, more preferably 40 kPa to 10 Pa).

(Step D)

Step D is a step of treating a precured laminate comprised of a support 10, resist patterns 20, curable resin composition layer 30, and substrate 40 to cure the curable resin composition which forms the curable resin composition layer 30 to, as shown in FIG. 2(A, obtain a cured resin layer 30a.

The curing conditions when causing the curable resin composition layer 30 to cure may be selected in accordance with the type of the curing agent which is contained in the curable resin composition layer 30, but the temperature is usually 130 to 230° C., preferably 150 to 200° C. Further, the curing time is usually 20 to 300 minutes, preferably 40 to 150 minutes. Note that, in the method of production of the present invention, when hot press bonding the substrate 40 to the curable resin composition layer 30, it is possible to perform the hot press bonding under the above the conditions so as to simultaneously perform the hot press bonding and curing of the curable resin composition layer 30.

(Step E)

Step E is a step of peeling off the support 10 from the curable resin composition layer 30 before curing or the cured resin layer 30a and resist pattern 20 after curing as shown in FIG. 2(A) before curing the curable resin composition layer 30 or after curing it at the above-mentioned Step D. That is, in the method of production of the present invention, after the above-mentioned Step C or after the above-mentioned Step D, the support 10 is peeled off. Note that, in the method of production of the present invention, from the viewpoint of peeling off the support 10 well, when peeling off the support 10 at either a timing before curing the curable resin composition layer 30 or after curing the curable resin composition layer 30, it is preferable to peel off the support 10 after cooling the laminate down to room temperature.

(Step F)

Step F is a step of peeling off or dissolving the resist patterns 20 to remove the resist patterns 20 from the cured resin layer 30a so as to, as shown in FIG. 2(B), form the substrate 40 having the cured resin layer 30a having the relief structures.

The method of peeling off the resist patterns 20 is not particularly limited, but the method of dipping the substrate 40 having the resist patterns 20 and cured resin layer 30a in a solution enabling the resist patterns 20 to be peeled off etc. may be mentioned. As the solution for peeling off the resist patterns 20, for example, amines or sodium hydroxide or other aqueous solution (peeling solution) may be used. Specifically, the method of dipping with shaking the substrate 40 having the resist patterns 20 and cured resin layer 30a into a 60 to 80° C. aqueous solution of sodium hydroxide of a concentration of 60 g/liter for 1 to 50 minutes so as to peel off the resist patterns 20 etc. may be used.

The method of dissolving the resist patterns 20 is not particularly limited, but the method of dipping the substrate 40 having the resist patterns 20 and cured resin layer 30a in a solution able to dissolve the resist patterns 20 etc. may be mentioned. As the solution for dissolving the resist patterns 20, for example, a solution of permanganate or other oxidizing compound (desmearing solution) etc. may be used. Specifically, the method of capping with shaking the substrate 40 having the resist patterns 20 and cured resin layer 30a in a 60 to 80° C. aqueous solution of sodium permanganate of a concentration of 60 g/liter and sodium hydroxide of a concentration of 20 g/liter for 1 to 50 minutes so as to dissolve the resist patterns 20 etc. may be used.

Further, it is also possible to jointly use ultrasonic waves when dipping the resist patterns 20 in the peeling solution or desmearing solution.

Further, in the method of production of the present invention, when using such a solution of a permanganate or other oxidizing compound (desmearing solution) to dissolve the resist patterns 20, it is preferable to use the action of such a desmearing solution to dissolve the resist patterns 20 and roughen the surface of the cured resin layer 30a as surface roughening treatment. The conditions at the time of surface roughening treatment of the cured resin layer 30a can, for example, be suitably adjusted by adjusting the temperature and time when dipping with shaking the substrate in the desmearing solution. By roughening the surface of the cured resin layer 30a in surface roughening treatment, when forming the fine, wirings 50 in the recesses of the cured resin layer 30a in the later explained Step G, it is possible to better improve the adhesion between the cured resin layer 30a and the fine, wirings 50.

Further, when roughening the surface of the cured resin layer 30a at Step F, it is possible to peel off or dissolve the resist patterns 20 and roughen the surface of the cured resin layer 30a simultaneously, but it is also possible to peel off and dissolve the resist patterns 20 and roughen the surface of the cured resin layer 30a separately. That is, it is also possible to peel off or dissolve the resist patterns 20, then roughen the surface of the cured resin layer 30a.

(Step G)

Step G is a step of using plating to form fine wirings 50 as shown in FIG. 2(C.) in the recesses of the relief structures which are formed at the cured resin layer 30a so as to obtain a circuit beard comprised of a cured resin layer 30a and fine wirings 50 comprised of a conductor provided on a substrate 40.

The method of forming the fine wirings 50 is not particularly limited, but from the viewpoint of enabling formation of conductors excellent in adhesion, use of the electroless plating method is preferable.

For example, when using electroless plating to form fine wirings 50, first, before forming a metal thin film on the surface of the cared resin layer 30a, the general practice is to deposit silver, palladium, zinc, cobalt, or other catalyst nuclei on the cured resin layer 30a. The method of depositing catalyst nuclei on the cured resin layer 30a is not particularly limited. For example, the method of dipping in a solution in which silver, palladium, zinc, cobalt, or other metal compound or their salt or complex is dissolved in water or alcohol or chloroform or other organic solvent to a concentration of 0.001 to 10 wt % (if necessary, including acid, alkali, complexing agent, reducing agent, etc.), then reduction of the metal etc. maybe mentioned.

As the electroless plating solution which is used in the electroless plating, a known self-catalyst type electroless plating solution may be used. It is not particularly limited in the type of metal, the type of reducing agent, the type of complexing agent, the concentration of hydrogen ions, the concentration of dissolved oxygen, etc. which are contained in the plating solution. For example, an electroless copper plating solution which contains ammonium hypophosphite, hypophosphoric acid, ammonium borohydride, hydrazine, formalin, etc. as a reducing agent; an electroless nickel-phosphorus plating solution which contains sodium hypophosphite as a reducing agent; an electroless nickel-boron plating solution which contains dimethylamineborane as a reducing agent; an electroless palladium plating solution; an electroless palladium-phosphorus plating solution which contains sodium hypophosphite as a reducing agent; an electroless gold plating solution; an electroless silver plating solution; an electroless nickel-cobalt-phosphorus plating solution which contains sodium hypophosphite as a reducing agent, or other electroless plating solution can be used.

After forming the metal thin layer, the substrate surface may be brought into contact with a rustproofing agent to make it rustproof. Further, after forming the metal thin layer, the metal thin layer may be heated to raise the adhesiveness. The heating temperature is usually 50 to 350° C., preferably 80 to 250° C. Note that, at this time, the heating may be performed under pressed conditions. As the pressing method at this time, for example, the method of using a hot press, a pressurizing and heating roll, and other physical pressing means may be mentioned. The pressure which is applied is usually 0.1 to 20 MPa, preferably 0.5 to 10 MPa. If in this range, a high adhesion between the metal thin film and the cured resin layer 30a or substrate 40 can be secured.

The thus formed metal thin film is grown with plating by electroplating or other wet plating is used to grow a plating (thick plating).

Therefore, the fine wirings 50 which are formed by this method are usually comprised of metal thin film and plating which is grown on the sane.

Electroless plating is formed on the entire surface of the resin, so the electroplating is also grown other than at predetermined patterns. For this reason, it is necessary to remove the metal thin film other than that of predetermined patterns. As the method of removal of the metal thin film, etching, polishing, etc. may be mentioned.

In the above way, according to the method of production of the present invention, as shown in FIG. 2(C), it is possible to produce a circuit board comprised of a substrate 40 provided with a cured resin layer 30a on which fine wirings 50 are formed in predetermined patterns. Further, according to such a method of production of the present invention, a mold such as shown in FIG. 1(A) comprised of a support 10 on which resist patterns 20 are formed is used to form patterns for forming fine wirings 50. The resist patterns 20 can be removed by a solution which can peeling off or dissolve the resist patterns 20, so it is possible to lower the height of the used resin layer 30a while forming the fine wirings 50 well. Further, according to the method of production of the present invention, the cured resin layer 30a is patterned using resist patterns 20, so there is no need to impart photosensitivity to the material constituting the cured resin layer 30a and therefore the cured resin layer 30a can be made excellent in electrical characteristics (in particular, electrical insulating property). In particular, when using, as the material constituting the cured resin layer 30a, a material which has photosensitivity,there is the problem that the obtained cured resin layer ends up falling in electrical characteristics, but according to the method of production of the present invention, such a problem can be effectively solved.

Note that, in the present invention, circuit boards obtained by above-mentioned method of production of the present invention may he used as the substrates 40 and the above-mentioned Step A to Step G repeated to obtain a multilayer circuit board. At this time, when repeating the above-mentioned Step A to Step G, it is possible to form a multilayer circuit board, for example, by repeatedly laminating the cured resin layers 30a and fine wirings 50 on the surfaces formed with the cured resin layers 30a and fine wirings 50 in the circuit boards obtained by the above-mentioned method of production of the present invention. Alternatively, by forming the cured resin layers 30a and fine wirings 50 on the surfaces opposite to the surfaces formed with the cured resin layers 30a and fine wirings 50, that is, the exposed surfaces of the substrates 40 shown in FIG. 2(C), in the circuit boards obtained by the above-mentioned method of production of the present invention, it is possible to form a multilayer circuit board provided with cured resin layers 30a and fine wirings 50 on of surfaces. Further, it is also possible to obtain a multilayer circuit board by repeatedly laminating cured resin layers 30a and fine wirings 50 on the cured resin layers 30a and fine wirings 50 which are formed on the two surfaces.

The thus obtained circuit board and multilayer circuit board of the present invention can, for example, be suitably used in a mobile phone, PHS, notebook PC, PDA (portable data assistant), portable television phone, personal computer, super computer, server, router, liquid crystal projector, engineering work station (EWS), pager, word processor, television, viewfinder type or monitor direct viewing type video tape recorder, electronic assistant, electronic desktop computer, car navigation system, POS terminal, device provided with a touch panel, or various other electronic devices.

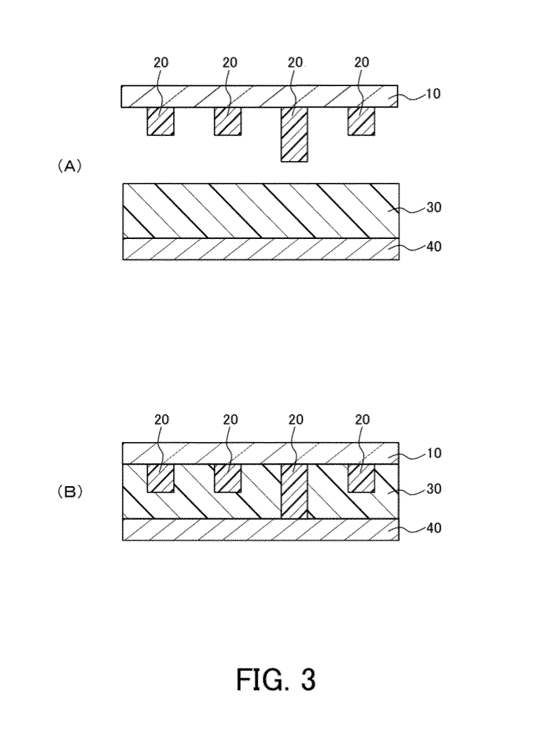

Note that, in the method of production of the present invention, it is also possible to employ a method where, instead of the above-mentioned Step B and Step C, the following Step B′ and Step C′ are used to obtain a precured laminate comprised of the support 10, resist patterns 20, and curable resin composition layer 30 and substrate 40. Here, FIG. 3 is a view which shows a method of production of a circuit board according to another embodiment of the present invention.

The other method of production of the present invention has the following steps:

(Step A) Step of forming resist patterns 20 on a support 10 by a photoresist to obtain a support with resist patterns (see FIG. 1(A)).

(Step B′) Step of forming a curable resin composition layer 30 comprised of a curable resin composition on a substrate 40 to obtain a curable resin composition substrate (see FIG. 3(A)).

(Step C′) Step of making the resist patterns 20 at the support with resist patterns and the curable resin composition layer 30 of the curable resin composition substrate into contact to laminate them so as to embed the resist patterns 20 in the curable resin composition layer 30 (see FIG. 3(B)).

(Step D) Step of making the curable resin composition which forms the curable resin composition layer 30 cure so as to rake the curable resin composition layer 30 a cured resin layer 30a (see FIG. 2(A)).

(Step E) Step of peeling off the support 10 from the curable resin composition layer 30 or the cured resin layer 30a and the resist patterns 20 before or after making the curable resin composition cure (see FIG. 2(A)).

(Step F) Step of peeling off or dissolving the resist patterns 20 so as to remove tie resist patterns 20 from the cured resin layer 30a thereby to form a cured resin layer 30a which has relief structures (see FIG. 2(B)).

(Step G) Step of using plating to form fine wirings 50 at the recesses of the relief structures which are formed at the cured resin layer 30a (see FIG. 2(C)).

Note that, Step A and Step D to Step G are similar to the above-mentioned method, so below, Step B′ and Step C′ will be explained in detail.

(Step B′)

Step B′ is a step of forming a curable resin composition layer 30 comprised of a curable resin composition on the substrate 40 to obtain the curable resin composition substrate which is shown in FIG. 3(A).

The method of forming the curable resin composition layer 30 on the substrate 40 is not particularly limited, but the method of bonding on the substrate 40 a film-shaped or sheet-shaped article of the curable resin composition may be mentioned. Note that, in this case, as the curable resin composition and substrate 40, ones similar to those illustrated in the above-mentioned Step B and Step C may be used.

Further, the film-shaped or sheet-shaped article of the curable resin composition can, for example, be obtained by forming the curable resin composition by the solution casting method, melt casting method, etc., but among these as well, use of the solution casting method for production is preferable. When using the solution casting method for forming, it is possible to coat a varnish of the curable resin composition on a support, then dry off the organic solvent so as to obtain a film-shaped or sheet-shaped article of the curable resin composition. Note that, the varnish of the curable resin composition can be prepared in the same way as the above-mentioned Step B.

As the support which is used in the solution casting method, a resin film (carrier film), metal foil, etc. may be mentioned. As the resin film, usually a thermoplastic resin film is used. Specifically, a polyethylene terephthalate film, polypropylene film, polyethylene film, polycarbonate film, polyethylene naphthalate film, polyarylate film, nylon film, etc. may be mentioned. Among these resin films, due to the excellent heat resistance, chemical resistance, peelability after lamination, etc., a polyethylene terephthalate film and polyethylene naphthalate film are preferable. As the metal foil, for example, copper foil, aluminum foil, nickel foil, chromium foil, gold foil, silver foil, etc. may be mentioned. Due to the excellent conductivity and low price, copper foil, in particular electrolytic copper foil or rolled copper foil, is suitable. The thickness of the support is not particularly limited, but from the viewpoint of the workability etc., it is usually 1 to 150 μm, preferably 2 to 100 μm, more preferably 3 to 50 μm.

As the coating method, a dip coat, roll coat, curtain coat, die coat, slit coat, or other method may be mentioned. Further, the conditions for drying to remove the organic solvent are suitably selected in accordance with the type of the organic solvent. The drying temperature is usually 20 to 300° C., preferably 30 to 200° C., while the drying time is usually 30 seconds to 1 hour, preferably 1 minute to 30 minutes.

Further, the thickness of the film-shaped or sheet shaped article is usually 0.1 to 150 μm, preferably 0.5 to 100 μm, more preferably 1 to 80 μm.

Next, the thus obtained film-shaped or sheet-shaped article of the curable resin composition is bonded with the substrate 40 to thereby obtain the substrate 40 which is provided with the curable resin composition layer 30 shown in FIG. 3(A). To bond the film-shaped or sheet-shaped article of the curable resin composition with the substrate 40, usually the film-shaped or sheet-shaped article with the support is superposed on the substrate 40 to contact the conductor circuit layer provided there, then a press laminator, press, vacuum laminator, vacuum press, roll laminator, or other press machine is used for hot press bonding (lamination) to make the two bond so that there is substantially no clearance present at the interface between the substrate 40 surface and article. The hot press bonding is preferably performed in a vacuum so as to improve the ability of the conductor circuit layer which is provided at the substrate 40 to be embedded in the curable resin composition layer 30 and suppress the formation of bubbles etc. The temperature at the time of hot press bonding is usually 30 to 250° C., preferably 70 to 200° C., the press bonding force is usually 10 kPa to 20 MPa, preferably 100 kPa to 10 MPa, the press bonding time is usually 30 seconds to 5 hours, preferably 1 minute to 3 hours, and the atmosphere is reduced in pressure to usually 100 kPa to 1 Pa, preferably 40 kPa to 10 Pa.

(Step C′)

Step C′ is a step of making the resist patterns 20 at the support with resist patterns (support 10 provided with resist patterns 20) obtained in the same way as the above-mentioned Step A and the curable resin composition layer 30 of the curable resin composition substrate (substrate 40 provided with curable resin composition layer 30) into contact to laminate them while embedding the resist patterns n in the curable resin composition layer 30 to obtain, as shown in FIG. 3(B), a precured laminate comprised of a support 10, resist patterns 20, curable resin composition layer 30, and substrate 40.

The method of lamination to embed the resist patterns 20 in the curable resin composition layer 30 is not particularly limited, but the method of superposing the support with resist patterns (support 10 provided with resist patterns 20) and the curable resin composition substrate (substrate 40 provided with curable resin composition layer 30) so that the resist patterns 20 and the curable resin composition layer 30 abut and using a press laminator, press, vacuum laminator, vacuum press, roll laminator, or other press machine for hot press bonding (lamination) and bonding the two so that substantially no clearance is present at their interface may be mentioned. The hot press bonding is preferably performed under a vacuum so as to improve the ability of the resist patterns 20 to be embedded in the curable resin composition layer 30 and suppress the formation of bubbles etc. The temperature at the time of hot press bonding is usually 30 to 250° C., preferably 70 to 200° C., the press bonding force is usually 10 kPa to 20 MPa, preferably 100 kPa to 10 MPa, the press bonding time is usually 30 seconds to 5 hours, preferably 1 minute to 3 hours, and the atmosphere is reduced in pressure to usually 100 kPa to 1 Pa, preferably 40 kPa to 10 Pa.

Further, by using a precured laminate comprised of a support 10, resist patterns 20, curable, resin composition layer 30, and substrate 40 obtained in this way and performing a similar operation to the above-mentioned Step D to Step G, it is possible to produce, as shown in FIG. 2(C), a circuit beard comprised of a substrate 40 on which is provided a cured resin layer 30a on which fine wirings 50 are formed by predetermined patterns. Further, according to another method of production of the present invention, in the same way as above, a mold comprised of a support 10 on which resist patterns 20 are formed such as shown in FIG. 3(A) is used to form patterns for forming fine wirings 50. The resist patterns 20 can be removed by a solution which can peeling off or dissolve the resist patterns 20, so it is possible to lower the height of the cured resin layer 30a while forming the fine wirings 50 well. Further, according to another method of production of the present invention, the cured resin layer 30a is patterned using resist patterns 20, so there is no need to impart photosensitivity to the material constituting the cured resin layer 30a and therefore the cured resin layer 30a can be made excellent in electrical characteristics (in particular, electrical insulating property).

Note that, in the present invention, circuit boards obtained by the other method of production of the present invention may be used as the substrates 40 and the above-mentioned Step A, Step B′, Step C′, and Step D to Step G repeated to obtain a multilayer circuit board. Note that, as the aspect of the multilayer circuit board, for example, one similar to the above can be adopted.

### EXAMPLES

Below, examples and comparative examples will be given to explain the present invention in more detail. Note that, in the examples, “parts” and “%” are based on weight unless indicated otherwise.

### Example 1

(Fabrication of Shaping Mold)

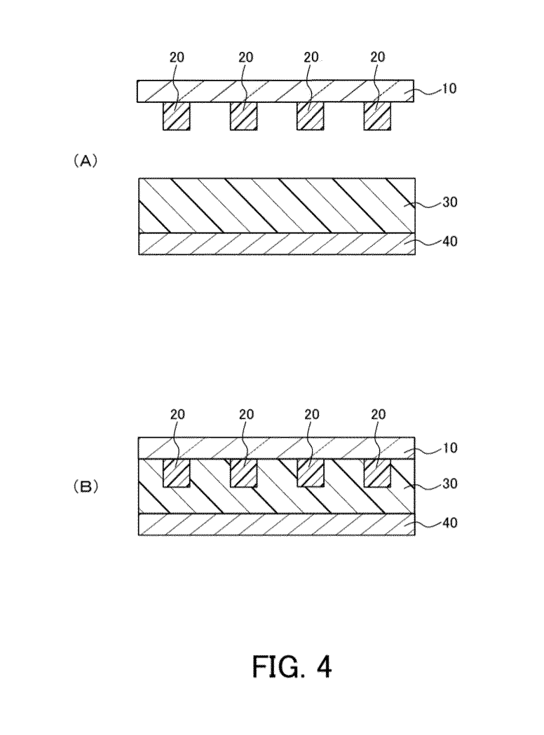

On release type polyethylene terephthalate (NSL-6, made by Fujimori Kogyo Co., Ltd.), a thickness 15 μm dry film resist (SUNFORT UFG158, made by Asahi Kasei E-materials) was laminated to obtain a laminate comprised of release type polyethylene terephthalate and a dry film resist. Note that, the lamination was performed by warming the release type polyethylene terephthalate to 50° C. and using a roll laminator under conditions of a laminate speed of 1.5 m/min, roll pressure of 0.3 MPa, and roll temperature of 105° C. Next, the obtained laminate was exposed and developed using a quartz glass chrome mask to thereby obtain a shaping mold such as shown in FIG. 3(A) comprised of a support 10 on which resist patterns 20 are formed (support with resist patterns). Note that, the exposure conditions at this time were made an amount of exposure of 60 mJ/cm² using a contact exposure apparatus. Further, the development was performed using a 1% sodium carbonate aqueous solution under conditions of a temperature of 30° C. and 30 seconds. Further, as the shaping mold, one which can form parallel line patterns of L/S=3 μm/3 μm, height 15 μm was prepared. That is, in the example which is shown in FIG. 3(A), the example is shown where the heights of the resist patterns 20 are made different so that part of the resist patterns 20 contact the substrate 40, but in this example, as shown in FIG. 4(A) and FIG. 4(B), the heights of the resist patterns 20 were made 15 μm. in all cases and there was no contact with the substrate 40.

(Fabrication of Buildup Film-Substrate Laminate)

On the other hand, separate from the above, a buildup film-substrate substrate laminate comprised of a core substrate constituted by an FR-4 material (glass epoxy resin substrate) on the two surfaces of which buildup films (ZS-100, made by Zeon Corporation, curable resin composition film mainly comprised of carboxyl-group containing alicyclic olefin polymer) were laminated was prepared. Note that, the buildup film-substrate laminate is a laminate comprised of the curable resin composition layer 30 and the substrate 40 shown in FIG. 3(A), the buildup film corresponds to the curable resin composition layer 30, and the core substrate constituted by the FR-4 material corresponds to the substrate 40. Note that, in the example shown in FIG. 3(A), an example where only one surface of the substrate 40 was formed with the curable resin composition layer 30 was shown, but in the present example, both surfaces of the substrate 40 were formed with curable resin composition layers 30.

(Fabrication of Precured Laminate)

Further, two of the above obtained shaping molds were prepared. On buildup films laminated on the two surfaces of a core substrate, the two prepared shaping molds (supports with resist patterns) were bonded so that the surfaces on which the resist patterns 20 were formed faced each other and were embedded to obtain a precured laminate such as shown in FIG. 3(B) comprised of supports 10, resist patterns 20, curable resin composition layers 30, and a substrate 40. Note that, in the example which is shown in FIG. 3(B), the example where only one surface of the substrate 40 was formed with a support 10, resist patterns 20, and curable resin composition layer 30, but in the present example, both surfaces of the substrate 40 were formed with supports 10, resist patterns 20, and curable resin composition layers 30. Further, the lamination was performed by using an MVLP500 (Meiki Co., Ltd.) as a laminate apparatus, evacuating this for 30 seconds, pressing through rubber under conditions of 90° C. by 0.7 MPa for 30 seconds, then hot pressing under conditions of 100° C. by 0.9 MPa for 60 seconds.

(Fabrication of Cured Laminate)

Next, the above obtained precured laminate was heated at 180° C. for 30 minutes to cure the buildup films forming the curable resin composition layers 30, then was allowed to cool to roam temperature, then the supports 10 constituted by the release type polyethylene terephthalate were peeled off to obtain a cured laminate comprised of resist patterns 20, cured resin layers 30a, and a substrate 40 such as shown in FIG. 2(A). Note that, in the example shown in FIG. 2(A), an example where only one surface of the substrate 40 was formed with resist patterns 20 and a cured resin layer 30a was shown, but in the present example, both surfaces of the substrate 40 were formed with resist patterns 20 and cured resin layers 30a.

(Resist Peeling Step)

The obtained cured laminate was dipped with shaking in a 60° C. aqueous solution which was prepared to contain a peeling solution (“Resist Strip IC-1”, made by Atotech) for 15 minutes while applying ultrasonic waves (130 W, 42 kHz), then rinsed.

(Swelling Step)

The obtained cured laminate was dipped with shaking in a 60° C. aqueous solution which was prepared to contain a swelling solution (“Swelling Dip Securiganth P”, made by Atotech, “Securiganth” is a registered trademark) 500 ml/liter and sodium hydroxide 3 g/liter for 15 minutes while applying ultrasonic waves (130 W, 42 kHz), then rinsed.

(Oxidation Step)

Next, the swelled laminate was dipped with shaking in an 80° C. aqueous solution which was prepared to contain an aqueous solution of permanganate (“Concentrate Compact CP”, made by Atotech) 640 ml/liter and a concentration of sodium hydroxide 40 g/liter for 15 minutes, then rinsed. Due to this oxidation step, the resist patterns 20 were removed to obtain a laminate such as shown in FIG. 2(B) comprised of cured resin layers 30a and substrate 40. Note that, in the example shown in FIG. 2(B), an example where only one surface of the substrate 40 was formed with the cured resist layer 30a was shown, but in the present example, both surfaces of the substrate 40 were formed with cured resin layers 30a. Further, at the oxidation step, the resist patterns 20 were removed and the surfaces of the cured resin layers 30a were roughened.

(Neutralization-Reduction Step)

Continuing after this, the oxidized laminate was dipped with shaking in a 40° C. aqueous solution which was prepared to contain a hydroxyamine sulfate aqueous solution (“Reduction Securiganth P 500”, made by Atotech, “Securiganth” is a registered trademark) 100 ml/liter and sulfuric acid 35 ml/liter for 5 minutes to neutralize and reduce it, then rinsed.

(Cleaner-Conditioner Step)

Next, the neutralized and reduced laminate was clipped with shaking in a 50° C. aqueous solution which was prepared to contain a cleaner-conditioner aqueous solution (“Alcup MCC-6-A”, made by Uyemura, “Alcup” is a registered trademark) concentration of 50 ml/liter for 5 minutes for cleaning and conditioning. Next, the laminate was dipped with shaking in a 40° C. rinsing water for 1 minute, then rinsed.

(Soft Etching Step)

Next, the cleaned and conditioned laminate was clipped with shaking in an aqueous solution which was prepared to contain a sulfuric acid concentration of 20 g/liter and sodium persulfate of 100 g/liter at room temperature for 2 minutes for soft etching, then rinsed.

(Pickling Step)

Next, the soft etched laminate was dipped with shaking in an aqueous solution which was prepared to contain a sulfuric acid concentration of 100 g/liter at room temperature for 1 minute for pickling, then rinsed.

(Catalyst Imparting Step)

Next, the pickled laminate was dipped with shaking in a 60° C. Pd salt-containing plating catalyst aqueous solution which was prepared to contain Alcup Activator MAT-1-A (product name, made by Uyemura, “Alcup” is a registered trademark) 200 ml/liter, Alcup Activator MAT-1-B (product name, made by Uyemura, “Alcup” is a registered trademark) 30 ml/liter, and sodium hydroxide 0.35 g/liter for 5 minutes, then rinsed.

(Activation Step)

Next, the catalyzed laminate was dipped with shaking in an aqueous solution which was prepared to contain Alcup Peducer MAB-4-A (product name, made by Uyemura, “Alcup” is a registered trademark) 20 ml/liter and Alcup Reducer MAB-4-B (product name, made by Uyemura, “Alcup” is a registered trademark) 200 ml/liter at 35° C. for 3 minutes to reduce the plating catalyst, then rinsed.

(Accelerator Treatment Step)

Next, the activated laminate was dipped in an aqueous solution which was prepared to contain Alcup Accelerator MEL-3-A (product name, made by Uyemura, “Alcup” is a registered trademark) 50 ml/liter at room temperature for 1 minute.

(Electroless Plating Step)

The thus obtained laminate was dipped in an electroless copper plating solution which was prepared to contain Thru-Cup PEA-6-A (product name, made by Uyemura, “Thru-Cup” is a registered trademark) 100 ml/liter, Thru-Cup PEA-6-B-2X (product name, made by Uyemura) 50 ml/liter, Thru-Cup PEA-6-C (product name, made by Uyemura) 14 ml/liter, Thru-Cup PEA-6-D (product name, made by Uyemura) 15 ml/liter, Thru-Cup PEA-5-E (product name, made by Uyemura) 50 ml/liter, and 37% formalin aqueous solution of 5 ml/liter, while blowing in air, at a temperature of 35° C. for 20 minutes to treat it by electroless copper plating and form an electroless plating film on the laminate surface (surface of cured resin layer 30a). Next, this was annealed in the air atmosphere at 150° C. for 30 minutes.

(Degreasing and Pickling Step)

Next, the annealed laminate was dipped in a 50° C. aqueous solution which was prepared to contain PB242D (product name, made by Ebara-Udylite) 100 g/liter for 5 minutes to degrease it, then the degreased laminate was dipped in an aqueous solution which was prepared to contain a sulfuric acid concentration of 100 g/liter at room temperature for 2 minutes for pickling, then rinsed.

(Electroplating Step)

Next, in an aqueous solution which was prepared to contain copper sulfate 200 g/liter, sulfuric acid 50 g/liter, 32% concentrated hydrochloric acid 0.05 ml/liter, FVF-1A (product name, made by Uemura) 1 ml/liter, FVF-B (product name, made by Uyemura) 10 ml/liter, and FVF-R (product name, made by Uyemura) 2 ml/liter (electrolytic solution), the degreased and pickled laminate was tapped and set at the cathode side and a phosphorous copper plate was tapped and set at the anode side. While blowing air, at ram temperature, a DC power source was used to run power for electrolytic copper plating to form an electrolytic copper plating film on a metal layer formed by electroless plating. When the electroless copper plating was sufficiently filled in the recesses of the cured resin layer 30a formed by removal of the resist patterns 20 (at the time of filling by the electroless copper plating), the thickness of the electroless copper plating layer farmed at the parts other than the recesses was 2 μm.

(Etching Step)

The electroless copper plating layer which was formed at the parts other than the recesses (above-mentioned parts of thickness 2 μm) was etched using HyperEtch “HE-500” (product name, made by Ebara-Udylite) by spray treatment, pickled, then rinsed.

Next, this was dipped in an aqueous solution which was prepared to contain AT-21 (product name, made by Uyemura) 1 ml/liter at room temperature for 1 minute for rust-proofing, then was annealed in the air at 180° C. for 60 minutes to obtain a circuit board such as shown in FIG. 2(C) comprising a cured resin layer 30a, fine wirings 50, and substrate 40.

Further, the this obtained circuit board was comprised of the cured resin layer 30a and the fine wirings 50 formed well by parallel line patterns of L/S=3 μm/3 μm and height 15 μm. From the results, according to the method of production of the present invention, lowering of the height and further micronization of wirings become possible. Further, the material which forms the cured resin layer 30a need not to impart photosensitivity, so it was confirmed to be possible to obtain a circuit board which is excellent in electrical characteristics (in particular, electrical insulating property).

### REFERENCE SIGNS LIST

10 . . . support
20 . . . resist pattern
30 . . . curable resin composition layer
30a . . . cured resin layer
40 . . . substrate
50 . . . fine wirings

1-7. (canceled)

8. A method of production of a circuit board comprising:
a step of forming resist patterns on a support by a photoresist to obtain a support with resist patterns;
a step of forming a curable resin composition layer which is comprised of a curable resin composition on the resist patterns of the support with resist patterns;
a step of laminating a substrate on the curable resin composition layer;
a step of making the curable resin composition which forms the curable resin composition layer cure to make the curable resin composition layer a cured resin layer;
a step of peeling off the support from the curable resin composition layer or the cured resin layer and the resist patterns before or after making the curable resin composition cure;
a step of peeling off or dissolving the resist patterns so as to remove the resist patterns from the cured resin layer to form a cured resin layer which has relief structures; and
a step of forming fine wirings by plating recesses of the relief structures which are formed at the cured resin layer.

9. A method of production of a circuit board comprising:
a step of forming resist patterns on a support by a photoresist to obtain a support with resist patterns;
a step of forming a curable resin composition layer which is comprised of a curable resin composition on a substrate to obtain a curable resin composition substrate;
a step of making the resist patterns of the support with resist patterns and the curable resin composition layer of the curable resin composition substrate into contact to laminate them so as to embed the resist patterns in the curable resin composition layer;
a step of making the curable resin composition which forms the curable resin composition layer cure to make the curable resin composition layer a cured resin layer;
a step of peeling off the support from the curable resin composition layer or the cured resin layer and the resist patterns before or after making the curable resin composition cure;
a step of peeling off or dissolving the resist patterns so as to remove the resist patterns from the cured resin layer to form a cured resin layer which has relief structures; and
a step of forming fine wirings by plating recesses of the relief structures which are formed at the cured resin layer.

10. The method of production of a circuit board as set forth in claim 1 wherein the curable resin composition includes a curable resin constituted by an alicyclic olefin polymer.

11. The method of production of a circuit board as set forth in claim 2 wherein the curable resin composition includes a curable resin constituted by an alicyclic olefin polymer.

12. The method of production of a circuit board as set forth in claim 1 wherein the substrate has an electrical insulating layer, and a conductor circuit layer which is formed on one or both surfaces of the electrical insulating layer.

13. The method of production of a circuit board as set forth in claim 2 wherein the substrate has an electrical insulating layer, and a conductor circuit layer which is formed on one or both surfaces of the electrical insulating layer.

14. The method of production of a circuit board as set forth in claim 1 further comprising
a step of roughening the surface of the cured resin layer simultaneously with peeling off or dissolving the resist patterns, or after peeling off or dissolving the resist patterns.

15. The method of production of a circuit board as set forth in claim 2 further comprising
a step of roughening the surface of the cured resin layer simultaneously with peeling off or dissolving the resist patterns, or after peeling off or dissolving the resist patterns.

16. The method of production of a circuit board as set forth in claim 1 wherein the steps are performed on both surfaces of the substrate so as to form fine wirings in recesses of the cured resin layers which have relief structures at both surfaces of the substrate.

17. The method of production of a circuit board as set forth in claim 2 wherein the steps are performed on both surfaces of the substrate so as to form fine wirings in recesses of the cured resin layers which have relief structures at both surfaces of the substrate.

18. A circuit board obtained by a method of production a as set forth in claim 1.

19. A circuit board obtained by a method of production a as set forth in claim 2.
